(19) United States
(12) Patent Application Publication
(10) Pub. No.: US 2023/0078165 A1
(43) Pub. Date: Mar. 16, 2023

(54) LIGHT EMITTING DEVICE, METHOD OF MANUFACTURING LIGHT EMITTING DEVICE, AND IMAGE DISPLAY APPARATUS

(71) Applicants: SONY GROUP CORPORATION, Kanagawa (JP); SONY SEMICONDUCTOR SOLUTIONS CORPORATION, Kanagawa (JP)

(72) Inventors: Akira OHMAE, Kanagawa (JP); Toshio FUJINO, Tokyo (JP); Tatsuo OHASHI, Tokyo (JP); Yusuke KATAOKA, Tokyo (JP); Toyoharu OOHATA, Tokyo (JP); Goshi BIWA, Tokyo (JP)

(73) Assignees: SONY GROUP CORPORATION, Tokyo (JP); SONY SEMICONDUCTOR SOLUTIONS CORPORATION, Kanagawa (JP)

(21) Appl. No.: 17/797,846

(22) PCT Filed: Feb. 10, 2021
(86) PCT No.: PCT/JP2021/005071

§ 371 Date: Aug. 5, 2022

(30) Foreign Application Priority Data
Feb. 20, 2020 (JP) 2020-027216

(51) Int. Cl. H01L 27/15; H01L 33/00; H01L 33/44; H01L 33/40; H01L 33/50

(52) U.S. Cl. CPC H01L 27/156; H01L 33/44; H01L 33/50; H01L 33/0093; H01L 33/405; H01L 2933/0025; H01L 2933/0041

(57) ABSTRACT

A light emitting device of an embodiment of the present disclosure includes: a substrate having a first surface and a second surface opposed to each other; semiconductor stacks provided on the first surface of the substrate and each including a first conductivity type layer, an active layer, and a second conductivity type layer that are stacked in order from a side of the first surface, the semiconductor stacks including multiple light emitting regions configured to emit light; and a separation section provided between the multiple light emitting regions and having a top surface at a position higher than the active layer in a direction of a normal to the first surface of the substrate.

### TECHNICAL FIELD

The present disclosure relates, for example, to a light emitting device including multiple light emitting sections, a method of manufacturing the light emitting device, and an image display apparatus including the light emitting device.

### BACKGROUND ART

Recently, an image display apparatus that has a light emitting element such as a light emitting diode (LED) for each pixel has become widespread. As a method of performing element separation between pixels, for example, PTL 1 discloses a wavelength tunable laser module in which stacked structures of semiconductors are separated from each other by wet etching.

### Citation List

### Patent Literature

PTL 1: Japanese Unexamined Patent Application Publication No. 2014-56264

### SUMMARY OF THE INVENTION

Incidentally, an improvement in light emission efficiency and a reduction in size are demanded of LEDs having multiple light emitting regions that are used as light sources of display pixels.

It is desirable to provide a light emitting device, a method of manufacturing a light emitting device, and an image display apparatus that make it possible to improve light emission efficiency and to achieve a reduction in size.

A light emitting device of an embodiment of the present disclosure includes: a substrate having a first surface and a second surface opposed to each other; semiconductor stacks provided on the first surface of the substrate and each including a first conductivity type layer, an active layer, and a second conductivity type layer that are stacked in order from a side of the first surface, the semiconductor stacks including multiple light emitting regions configured to emit light; and a separation section provided between the multiple light emitting regions and having a top surface at a position higher than the active layer in a direction of a normal to the first surface of the substrate.

A method of manufacturing a light emitting device of an embodiment of the present disclosure includes, after forming a separation section on a first surface of a substrate having the first surface and a second surface opposed to each other, forming semiconductor stacks with the separation section interposed therebetween, the semiconductor stacks each including a first conductivity type layer, an active layer, and a second conductivity type layer that are stacked in order from a side of the first surface, the semiconductor stacks including multiple light emitting regions configured to emit light.

An image display apparatus of an embodiment of the present disclosure includes multiple light emitting devices, and includes, as each of the multiple light emitting devices, the light emitting device of the embodiment of the present disclosure described above.

In the light emitting device of the embodiment of the present disclosure, the method of manufacturing the light emitting device of the embodiment, and the image display apparatus of the embodiment, the separation section having the top surface at a position higher than the active layer in the direction of the normal to the first surface of the substrate is provided between the multiple light emitting regions of the semiconductor stacks provided on the first surface side of the substrate and each including the first conductivity type layer, the active layer, and the second conductivity type layer that are stacked. The separation section is formed in advance on the first surface of the substrate. The semiconductor stacks including the multiple light emitting regions are separated from each other by the separation section at the time of crystal growth. This prevents damage to the semiconductor stacks resulting from a manufacturing process and makes a spacing between the light emitting regions smaller.

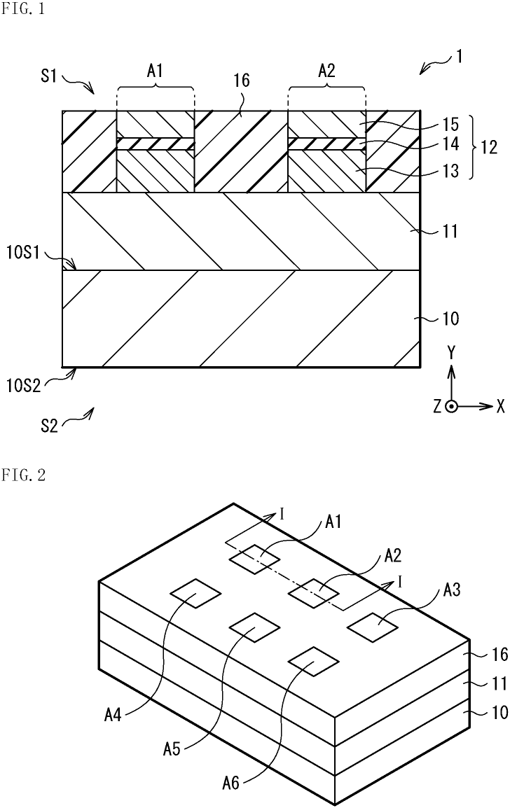

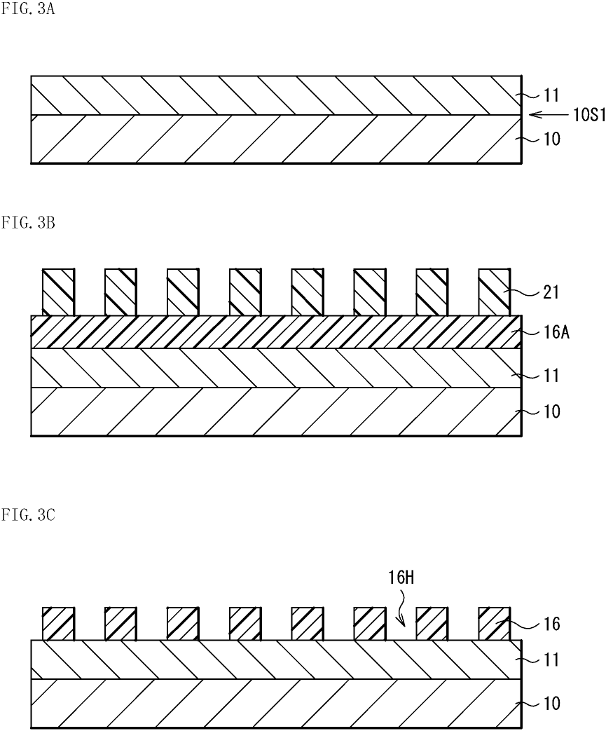

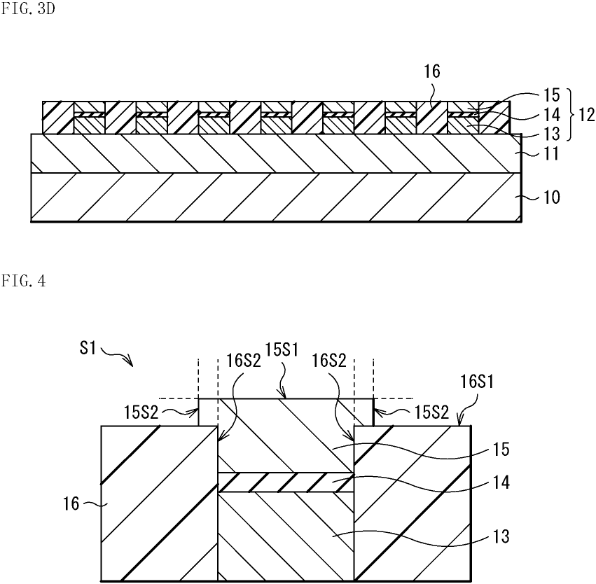

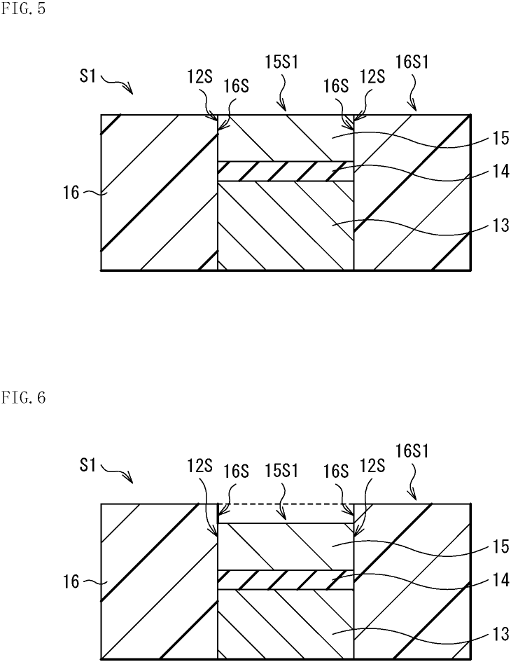

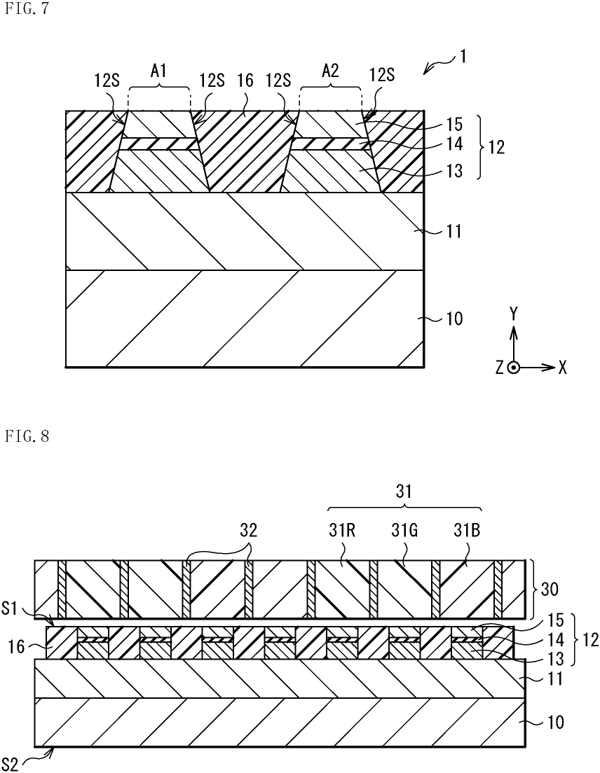

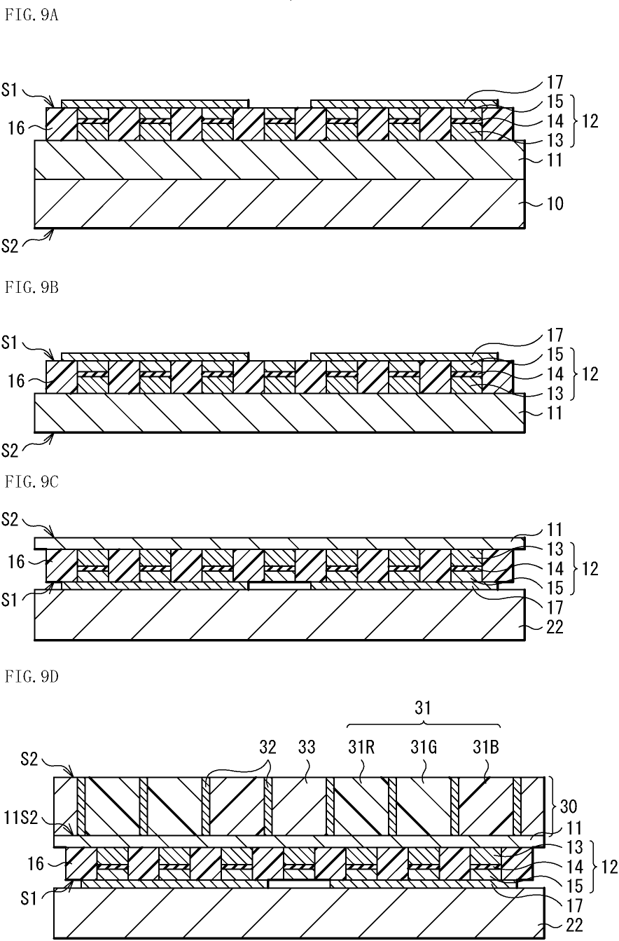

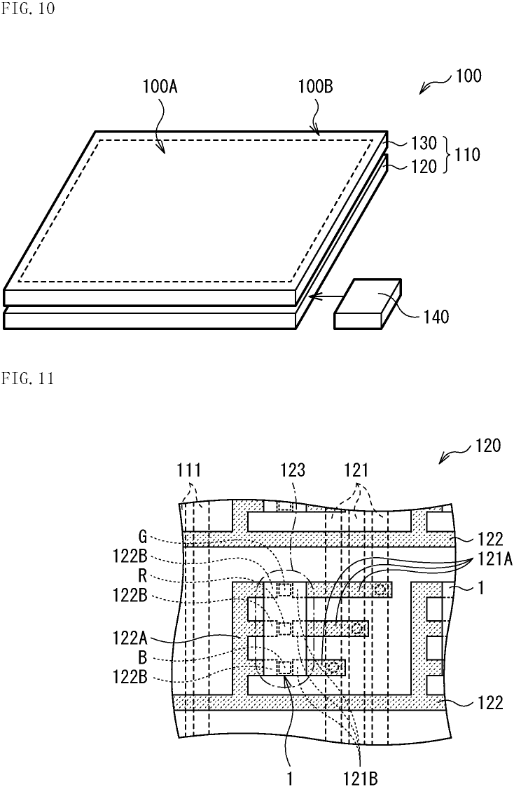

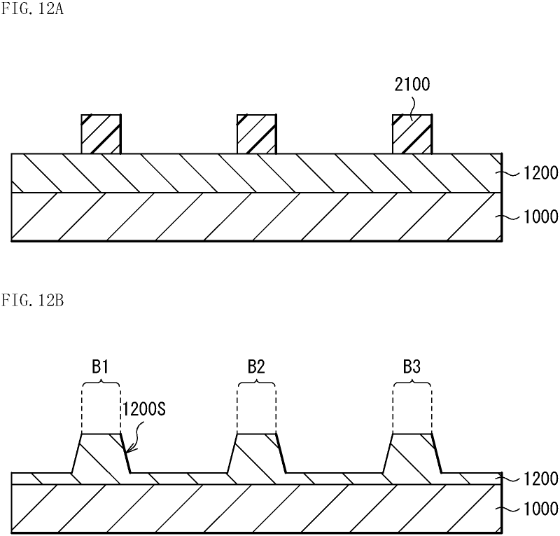

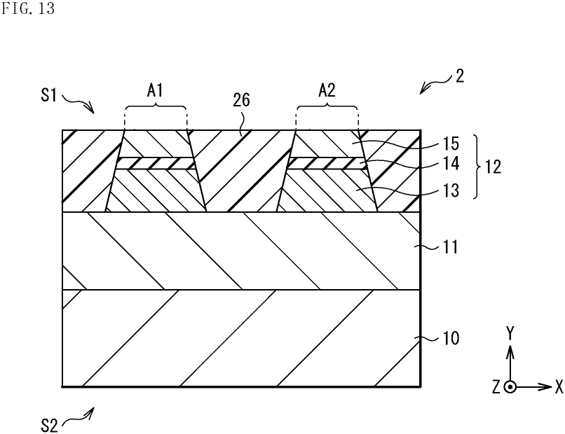

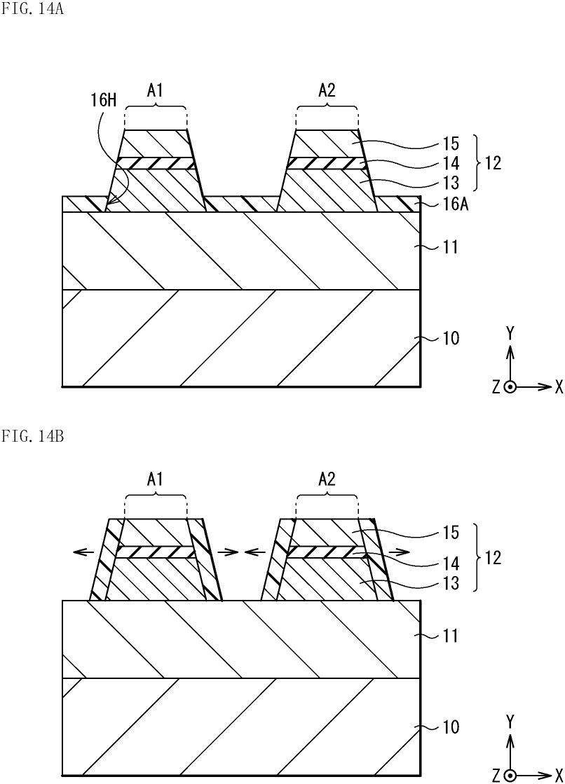

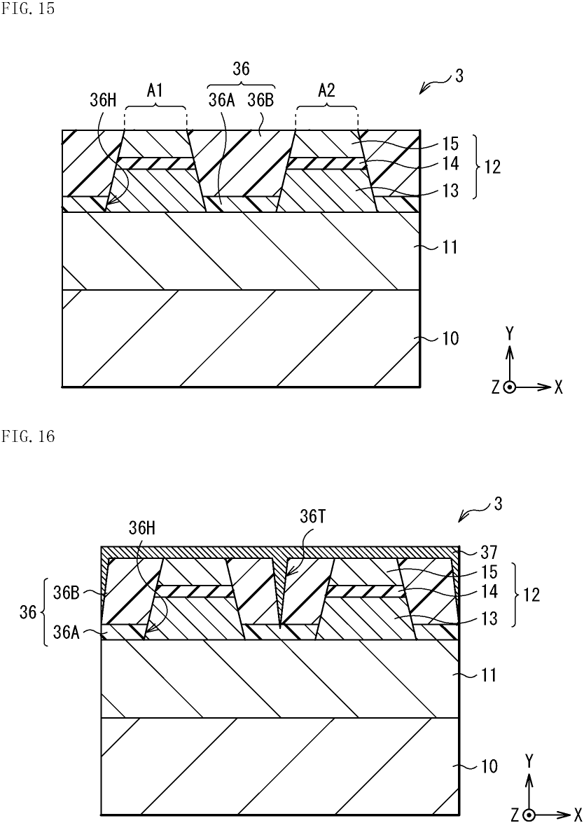

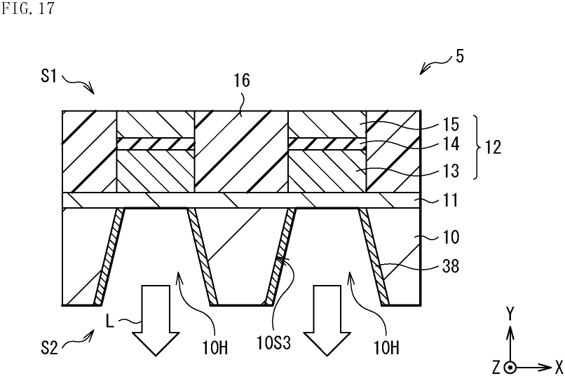

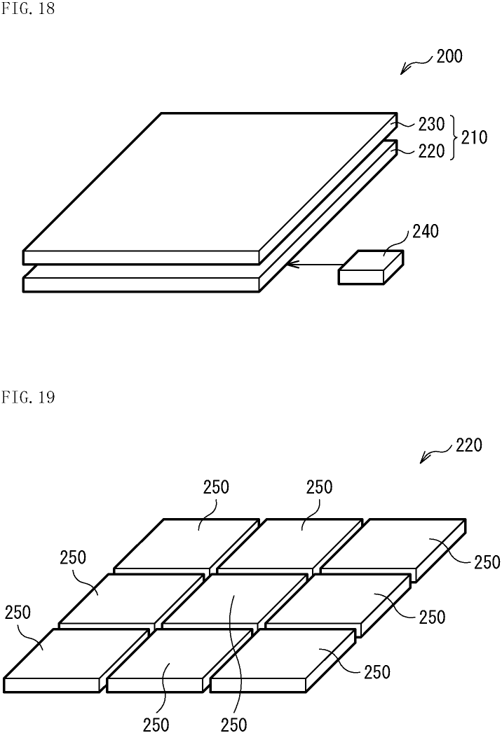

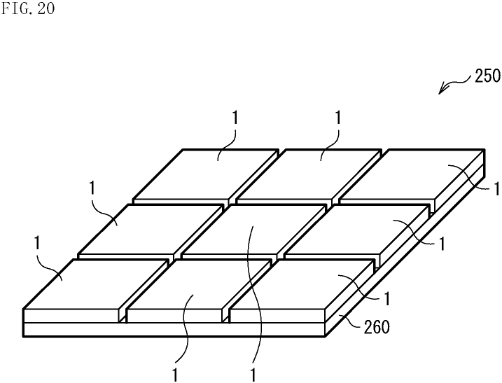

### BRIEF DESCRIPTION OF DRAWINGS

[FIG. 1] FIG. 1 is a schematic cross-sectional diagram illustrating a configuration example of a light emitting device according to a first embodiment of the present disclosure.

[FIG. 2] FIG. 2 is a perspective diagram illustrating a configuration example of the light emitting device illustrated in FIG. 1.

[FIG. 3A] FIG. 3A is a schematic cross-sectional diagram describing a method of manufacturing the light emitting device illustrated in FIG. 1.

[FIG. 3B] FIG. 3B is a schematic cross-sectional diagram illustrating a step subsequent to FIG. 3A.

[FIG. 3C] FIG. 3C is a schematic cross-sectional diagram illustrating a step subsequent to FIG. 3B.

[FIG. 3D] FIG. 3D is a schematic cross-sectional diagram illustrating a step subsequent to FIG. 3C.

[FIG. 4] FIG. 4 is a schematic cross-sectional diagram illustrating an example of a surface shape of the light emitting device illustrated in FIG. 1.

[FIG. 5] FIG. 5 is a schematic cross-sectional diagram illustrating another example of the surface shape of the light emitting device illustrated in FIG. 1.

[FIG. 6] FIG. 6 is a schematic cross-sectional diagram illustrating another example of the surface shape of the light emitting device illustrated in FIG. 1.

[FIG. 7] FIG. 7 is a schematic cross-sectional diagram illustrating another configuration example of the light emitting device according to the first embodiment of the present disclosure.

[FIG. 8] FIG. 8 is a schematic cross-sectional diagram illustrating a step subsequent to FIG. 3D.

[FIG. 9A] FIG. 9A is a schematic cross-sectional diagram illustrating another step subsequent to FIG. 3D.

[FIG. 9B] FIG. 9B is a schematic cross-sectional diagram illustrating a step subsequent to FIG. 9A.

[FIG. 9C] FIG. 9C is a schematic cross-sectional diagram illustrating a step subsequent to FIG. 9B.

[FIG. 9D] FIG. 9D is a schematic cross-sectional diagram illustrating a step subsequent to FIG. 9C.

[FIG. 10] FIG. 10 is a perspective diagram illustrating an example of a configuration of an image display apparatus including the light emitting device illustrated in FIG. 1.

[FIG. 11] FIG. 11 is a schematic diagram illustrating an example of a wiring layout of the image display apparatus illustrated in FIG. 10.

[FIG. 12A] FIG. 12A is a schematic cross-sectional diagram illustrating an example of a method of manufacturing a light emitting device of a comparative example.

[FIG. 12B] FIG. 12B is a schematic cross-sectional diagram illustrating a configuration subsequent to FIG. 12A.

[FIG. 13] FIG. 13 is a schematic cross-sectional diagram illustrating a configuration example of a light emitting device according to a second embodiment of the present disclosure.

[FIG. 14A] FIG. 14A is a schematic cross-sectional diagram describing a method of manufacturing the light emitting device illustrated in FIG. 13.

[FIG. 14B] FIG. 14B is a schematic cross-sectional diagram illustrating a step subsequent to FIG. 14A.

[FIG. 15] FIG. 15 is a schematic cross-sectional diagram illustrating a configuration example of a light emitting device according to Modification Example 1 of the present disclosure.

[FIG. 16] FIG. 16 is a schematic cross-sectional diagram illustrating a configuration example of a light emitting device according to Modification Example 2 of the present disclosure.

[FIG. 17] FIG. 17 is a schematic cross-sectional diagram illustrating a configuration example of a light emitting device according to Modification Example 3 of the present disclosure.

[FIG. 18] FIG. 18 is a perspective diagram illustrating another example of a configuration of an image display apparatus according to Modification Example 4 of the present disclosure.

[FIG. 19] FIG. 19 is a perspective diagram illustrating a configuration of a mounting substrate illustrated in FIG. 18.

[FIG. 20] FIG. 20 is a perspective diagram illustrating a configuration of a unit substrate illustrated in FIG. 19.

### MODES FOR CARRYING OUT THE INVENTION

In the following, some embodiments of the present disclosure are described in detail with reference to the drawings. It is to be noted that the following description is a mere example of the present disclosure, and the present disclosure is not limited to the following embodiments. In addition, the arrangement, dimensions, dimensional ratios, and the like of components illustrated in the drawings should not be construed as limiting the present disclosure. It is to be noted that the description is given in the following order.

1. First Embodiment (An example of a light emitting device in which a separation section that includes an insulator including a dielectric material and has a top surface at a position higher than an active layer is provided between light emitting sections)
1-1. Configuration of Light Emitting Device
1-2. Method of Manufacturing Light Emitting Device
1-3. Configuration of Image Display Apparatus
1-4. Workings and Effects

2. Second Embodiment (An example of a light emitting device in which a separation section that includes an undoped layer including a semiconductor material and has a top surface at a position higher than the active layer is provided between the light emitting sections)
2-1. Configuration of Light Emitting Device
2-2. Method of Manufacturing Light Emitting Device
2-3. Workings and Effects

3. Modification Examples
3-1. Modification Example 1 (An example of a light emitting device in which a separation section that includes a stack of an insulator including a dielectric film and an undoped layer is provided between the light emitting sections)
3-2. Modification Example 2 (An example of a light emitting device in which a contact electrode extending from a light emitting section is embedded in a groove of the separation section)
3-3. Modification Example 3 (An example of a light emitting device in which a substrate is provided with an opening through which light is to be extracted)
3-4. Modification Example 4 (Another example of an image display apparatus)

### 1. First Embodiment

FIG. 1 schematically illustrates an example of a cross-sectional configuration of a light emitting device (a light emitting device 1) according to a first embodiment of the present disclosure. FIG. 2 is a perspective diagram illustrating an example of a configuration of the light emitting device 1 illustrated in FIG. 1. Note that FIG. 1 illustrates a cross section taken along line I-I illustrated in FIG. 2. The light emitting device 1 is suitably applicable as a display pixel of an image display apparatus (an image display apparatus 100, see FIG. 10) that is what is called an LED display, and includes multiple light emitting sections (light emitting regions).

### 1-1. Configuration of Light Emitting Device

The light emitting device 1 includes a substrate 10, a semiconductor layer 11, semiconductor stacks 12 that configure the multiple light emitting sections (e.g., light emitting sections A1, A2, A3, A4, A5, and A6) to be driven independently of each other, and a separation section 16 provided between the multiple light emitting sections. In the light emitting device 1, the substrate 10 and the semiconductor layer 11 are stacked in this order, and the semiconductor stacks 12 configuring the multiple light emitting sections and the separation section 16 are provided on the semiconductor layer 11. The light emitting device 1 of the present embodiment is formed by, after forming the separation section 16 in advance on the semiconductor layer 11, forming each of semiconductor layers (a first conductivity type layer 13, an active layer 14, and a second conductivity type layer 15) configuring the semiconductor stack 12 by crystal growth. The separation section 16 has a top surface (a surface 16S1) at a position higher than the active layer 14.

The semiconductor stacks 12 each have a configuration in which, for example, the first conductivity type layer 13, the active layer 14, and the second conductivity type layer 15 are stacked in this order, and have a columnar shape, for example. The first conductivity type layer 13, the active layer 14, and the second conductivity type layer 15 each include, for example, an InGaN-based semiconductor material or an AlGaInP-based semiconductor material. As one example, the first conductivity type layer 13 may include a GaN layer doped with silicon (Si), for example. The active layer 14 may include an InGaN layer, for example. The second conductivity type layer 15 may include a GaN layer doped with magnesium (Mg), for example.

The separation section 16 electrically separates the multiple light emitting sections (e.g., the light emitting sections A1, A2, A3, A4, A5, and A6) from each other, and is provided in a lattice shape on the semiconductor layer 11, for example. The separation section 16 may include, for example, a dielectric material or an insulating material, such as an oxide material or a nitride material. Specifically, the separation section 16 may include, for example, silicon oxide (SiO), silicon nitride (SiN), or the like.

### 1-2. Method of Manufacturing Light Emitting Device

It is possible to manufacture the light emitting device 1 illustrated in FIG. 1 in the following manner, for example. FIGS. 3A to 3D illustrate an example of a method of manufacturing the light emitting device 1.

It is possible to form each of semiconductor layers configuring the light emitting device 1 (the semiconductor layer 11, the first conductivity type layer 13, the active layer 14, and the second conductivity type layer 15) by epitaxial crystal growth using, for example, a metal organic chemical vapor deposition (MOCVD: Metal Organic Chemical Vapor Deposition) method, a molecular beam epitaxy (MBE: Molecular Beam Epitaxy) method, or the like.

First, as illustrated in FIG. 3A, the semiconductor layer 11 including, for example, GaN, is formed as an underlying layer on a surface 10S1 of the substrate 10 into a thickness of 500 nm to 3000 nm, for example. Subsequently, as illustrated in FIG. 3B, a dielectric film 16A including, for example, silicon oxide (SiO), is formed on an entire surface of the semiconductor layer 11 into a thickness of, for example, 100 nm to 2000 nm, following which a resist film 21 having a predetermined pattern is formed on the dielectric film 16A.

Next, as illustrated in FIG. 3C, portions of the dielectric film 16A exposed from the resist film 21 are removed by, for example, etching, to thereby form openings 16H. The separation section 16 having a lattice shape is thereby formed on the semiconductor layer 11.

Subsequently, as illustrated in FIG. 3D, crystal growth is performed again as selective growth on the semiconductor layer 11 exposed in the openings 16H to thereby form the semiconductor stacks 12. Specifically, as the first conductivity type layer 13, for example, a GaN layer doped with silicon (Si) having a thickness of, for example, 100 nm to 1000 nm, as the active layer 14, for example, an InGaN layer having a thickness of, for example, 2 nm to 5 nm, and as the second conductivity type layer 15, for example, a GaN layer doped with magnesium (Mg) having a thickness of, for example, 50 nm to 300 nm, are grown in order. The semiconductor stacks 12 are thereby formed that includes the light emitting sections (e.g., the light emitting sections A1, A2, A3, A4, A5, and A6) electrically separated from each other by the separation section 16. The light emitting device 1 illustrated in FIG. 1 is completed thus.

FIGS. 4, 5, and 6 each schematically illustrate an example of a surface shape of the light emitting device 1. A top surface (a surface S1) of the light emitting device 1 including the semiconductor stacks 12 and the separation section 16 formed by the above-described method has a shape as described below. For example, as illustrated in FIG. 4, the second conductivity type layer 15 included in the semiconductor stack 12 may have a top surface (a surface 15S1) at a position higher than that of the top surface (the surface 16S1) of the separation section 16. Alternatively, as illustrated in FIG. 5, the top surface (the surface 15S1) of the second conductivity type layer 15 included in the semiconductor stack 12 and the top surface (the surface 16S1) of the separation section 16 may form one plane. Alternatively, the second conductivity type layer 15 included in the semiconductor stack 12 may have the top surface (the surface 15S1) at a position lower than that of the top surface (the surface 16S1) of the separation section 16. It is possible to form any of the surface shapes of the light emitting device 1 illustrated in FIGS. 4, 5, and 6 as desired by, for example, adjusting the crystal growth times of the first conductivity type layer 13, the active layer 14, and the second conductivity type layer 15 configuring the semiconductor stack 12.

In the light emitting device 1 of the present embodiment, in any case, the separation section 16 has the top surface (the surface 16S 1) at a position higher than the active layer 14 included in the semiconductor stack 12. Further, in the light emitting device 1 formed by the above-described method, as illustrated in FIGS. 5 and 6, in a case where the top surface (the surface 15S1) of the second conductivity type layer 15 is formed in the same plane as or at a lower position than that of the top surface (the surface 16S1) of the separation section 16, a side surface (a surface 16S2) of the separation section 16 is formed on a side surface (a surface S12S2) of the semiconductor stack 12 and on an extended line thereof. In contrast, in a case where the second conductivity type layer 15 has the top surface (the surface 15S1) at a position higher than that of the top surface (the surface 16S1) of the separation section 16, as illustrated in FIG. 4, a portion of a side surface (a surface 15S2) of the second conductivity type layer 15 is formed on an outer side relative to the side surface (the surface 16S2) of the separation section 16. In other words, the second conductivity type layer 15 higher than the top surface (the surface 16S1) of the separation section 16 is shaped to extend in part onto the top surface (the surface 16S1) of the separation section 16.

Note that although FIG. 1 and the like illustrate an example in which the side surface (the surface 12S2) of the semiconductor stack 12 and the side surface (the surface 16S2) of the separation section 16 are formed along a direction of the normal to a substrate surface, each of the side surfaces (the surfaces 12S2 and 16S2) may be an inclined surface, as illustrated in FIG. 7, for example.

In a case where the light emitting device 1 is used as, for example, a display pixel of the image display apparatus 100 to be described later, an optical film 30 including a color conversion layer (e.g., a color conversion layer 31) is formed thereafter on a front surface (the surface S1) side or a back surface (a surface S2) side of the light emitting device 1.

For example, in a case where the top surface (the surface 15S1, on the top surface (the surface S1) side of the light emitting device 1) of the second conductivity type layer 15 of the semiconductor stack 12 is to serve as a light extraction surface, as illustrated in FIG. 8, the color conversion layer 31 including a red color conversion layer 31R, a green color conversion layer 31G, and a blue color conversion layer 31B is disposed above the respective semiconductor stacks 12. At this time, for example, light blocking sections 32 are preferably formed between the respective color conversion layers 31R, 31G, and 31B. This makes it possible to reduce the occurrence of color mixture between adjacent pixels.

Note that as illustrated in FIG. 6, in the case of forming the top surface (the surface 15 S1) of the second conductivity type layer 15 at a position lower than that of the top surface (the surface 16S1) of the separation section 16, the color conversion layers 31R, 31G, and 31B may each be formed in a stepped portion between the second conductivity type layer 15 and the separation section 16. Further, in a portion of the color conversion layer 31 above the semiconductor stack 12 that is structurally not the light emitting region, any color conversion layer of the red color conversion layer 31R, the green color conversion layer 31G, and the blue color conversion layer 31B may be formed, or a transparent layer may be provided.

Furthermore, in a case where a bottom surface (the back surface (the surface S2) side of the light emitting device 1) of the first conductivity type layer 13 of the semiconductor stack 12 is to serve as the light extraction surface, first, as illustrated in FIG. 9A, a contact wiring line 17 including, for example, silver (Ag), ITO, or the like and continuous over three light emission sections (semiconductor stacks 12), for example, is formed on the top surface (the surface S1) of the light emitting device 1. Further, although not illustrated, bumps for electrically coupling a wiring substrate 22 described later and the first conductivity type layers 13 to each other are formed on the semiconductor layer 11 at peripheral parts or the like of the multiple light emitting sections (e.g., the light emitting sections A1, A2, A3, A4, A5, and A6), for example. Next, as illustrated in FIG. 9B, the substrate 10 is removed from the semiconductor layer 11.

Subsequently, as illustrated in FIG. 9C, the light emitting device 1 is flip-chip mounted, for example, on the wiring substrate 22. Specifically, the light emitting device 1 is mounted on the wiring substrate 22 via the contact wiring lines 17 and the bumps. As a result, the first conductivity type layers 13 of the semiconductor stacks 12 configuring the multiple light emitting sections (e.g., the light emitting sections A1, A2, A3, A4, A5, and A6) are electrically coupled to the wiring substrate 22 via the semiconductor layer 11 and the bumps, and the second conductivity type layers 15 are electrically coupled to the wiring substrate 22 via the contact wiring lines 17. Note that the wiring substrate 22 corresponds to, for example, a mounting substrate 120 of the image display apparatus 100 to be described later. Thereafter, the semiconductor layer 11 is thinned.

Lastly, as illustrated in FIG. 9D, on a back surface (a surface 11S2) of the thinned semiconductor layer 11, the optical film 30 including the red color conversion layer 31R, the green color conversion layer 31G, the blue color conversion layer 31B, and the like is disposed above the semiconductor stacks 12.

### 1-3. Configuration of Image Display Apparatus

FIG. 10 is a perspective diagram illustrating an example of an outline configuration of an image display apparatus (the image display apparatus 100). The image display apparatus 100 is what is called an LED display, and uses the light emitting device 1 of the present embodiment as a display pixel. The image display apparatus 100 includes, as illustrated in FIG. 10, for example, a display panel 110 and a control circuit 140 that drives the display panel 110.

The display panel 110 includes the mounting substrate 120 and a counter substrate 130 that are superimposed on each other. A surface of the counter substrate 130 serves as an image displaying surface, and has a display region 100A in the middle part and a frame region 100B as a non-display region around the middle part.

FIG. 11 illustrates an example of a wiring layout in a region on a surface of the mounting substrate on the counter substrate 130 side, the region corresponding to the display region 100A. As illustrated in FIG. 11, for example, multiple data wiring lines 121 are formed to extend in a predetermined direction and are arranged side by side at predetermined pitches in the region on the surface of the mounting substrate 120 corresponding to the display region 100A. In the region on the surface of the mounting substrate 120 corresponding to the display region 100A, for example, multiple scan wiring lines 122 are further formed to extend in a direction crossing (e.g., orthogonal) to the data wiring lines 121 and are arranged side by side at predetermined pitches. The data wiring lines 121 and the scan wiring lines 122 include, for example, an electrically conductive material such as Cu (copper).

The scan wiring lines 122 are formed on, for example, an outermost layer, and are formed on, for example, an insulating layer (not illustrated) formed on a surface of a base material. Note that the base material of the mounting substrate 120 is configured by, for example, a silicon substrate, a resin substrate, or the like, and the insulating layer on the base material includes, for example, silicon nitride (SiN), silicon oxide (SiO), aluminum oxide (A1O), or a resin material. Meanwhile, the data wiring lines 121 are formed in a layer different from the outermost layer that contains the scan wiring lines 122 (for example, a layer lower than the outermost layer), and are formed, for example, inside the insulating layer on the base material.

The vicinity of an intersection of the data wiring line 121 and the scan wiring line 122 is a display pixel 123, and a plurality of the display pixels 123 is arranged in a matrix in a display region 3A. The light emitting device 1 including, for example, three light emitting sections (e.g., light emitting sections 1R, 1G, and 1B) is mounted on each of the display pixels 123. Note that FIG. 11 illustrates an example case in which the three light emitting sections 1R, 1G, and 1B constitute one display pixel 123, and in which it is possible to output light of red from the light emitting section 1R, light of green from the light emitting section 1G, and light of blue from the light emitting section 1B.

The light emitting device 1 is provided with, for example, a pair of terminal electrodes for each of the light emitting sections 1R, 1G, and 1B, or one terminal electrode common to the light emitting sections 1R, 1G, and 1B and another terminal electrode for each of the light emitting sections 1R, 1G, and 1B. Further, the one terminal electrode is electrically coupled to the data wiring line 121, and the other terminal electrode is electrically coupled to the scan wiring line 122. For example, the one terminal electrode is electrically coupled to a pad electrode 121B at an end of a branch 121A provided at the data wiring line 121. Further, for example, the other terminal electrode is electrically coupled to a pad electrode 122B at an end of a branch 122A provided at the scan wiring line 122.

Each of the pad electrodes 121B and 122B is formed on, for example, the outermost layer, and is provided at a location where each of the light emitting device 1 is mounted, for example, as illustrated in FIG. 11. Here, the pad electrodes 121B and 122B include, for example, an electrically conductive material such as Au (gold).

The mounting substrate 120 is further provided with, for example, multiple pillars (not illustrated) that regulate a spacing between the mounting substrate 120 and the counter substrate 130. The pillars may be provided in a region facing the display region 100A, or may be provided in a region facing the frame region 100B.

The counter substrate 130 is configured by, for example, a glass substrate, a resin substrate, or the like. In the counter substrate 130, a surface on the light emitting device 1 side may be planarized, but is preferably a rough surface. The rough surface may be provided over the entire region that faces the display region 100A, or may be provided only in a region that faces the display pixels 123. The rough surface has fine irregularities, and light emitted from the light emitting sections 1R, 1G, and 1B enters the rough surface. It is possible to produce the irregularities on the rough surface by, for example, sandblasting, dry etching, or the like.

The control circuit 140 drives each of the display pixels 123 (each of the light emitting devices 1) on the basis of a picture signal. The control circuit 140 includes, for example, a data driver that drives the data wiring lines 121 coupled to the display pixels 123, and a scan driver that drives the scan wiring lines 122 coupled to the display pixels 123. For example, the control circuit 140 may be, as illustrated in FIG. 10, provided separately from the display panel 110 and coupled to the mounting substrate 120 via a wiring line, or may be mounted on the mounting substrate 120.

### 1-4. Workings and Effects

In the light emitting device 1 of the present embodiment, the semiconductor stacks 12 including the multiple light emitting sections (e.g., the light emitting sections A1, A2, A3, A4, A5, and A6) and the separation section 16 interposed between the multiple light emitting sections and having the top surface (the surface 16S 1) at a position higher than the active layers included in the semiconductor stacks 12 are provided on the semiconductor layer 11 formed on the substrate 10. The semiconductor stacks 12 and the separation section 16 are formed in the order of the separation section 16 and the semiconductor stacks 12 on the semiconductor layer 11. Specifically, the separation section 16 is formed in advance on the semiconductor layer 11, and thereafter, by performing crystal growth again, the semiconductor stacks 12 are formed in the openings 16H of the separation section 16 having a lattice shape. This makes it possible to form the light emitting sections (the semiconductor stacks 12) with narrow spacings between the light emitting sections and without damage thereto resulting from the manufacturing process. This will be described in the following.

As described above, an image display apparatus that has a light emitting element such as a light emitting diode (LED) for each pixel has recently become widespread, and is expected to achieve higher definition, for example. To achieve higher definition, a method of increasing an RGB integration density in a pixel is conceivable.

For a typical LED display which uses LEDs as the light sources, for example, a semiconductor stack 1200 serving as a basic pattern of the LEDs is crystal-grown on a substrate 1000 as illustrated 12A, following which resist films 2100 are formed on the semiconductor stack 12, and portions of the semiconductor stack 1200 exposed from the resist films 2100 are removed by, for example, dry etching to thereby produce light emitting sections B1, B2, and B3 corresponding to respective pixels and RGB as illustrated in FIG. 12B, for example. However, in a case where the above-described method is employed, it is necessary to secure sufficient separation width between the light emitting sections B1, B2, and B3, and an occupation rate of a separation section separating the light emitting sections B1, B2, and B3 from each other increases as the pixel size decreases. Further, a side surface (a surface 1200S) of each of the light emitting sections B1, B2, and B3 suffers damage due to the etching, and accordingly, there is a possibility that the light emission efficiency greatly decreases depending on the size of the light emitting sections.

To cope with this, in the present embodiment, after the semiconductor layer 11 is grown on the substrate 10, the separation section 16 is formed into a lattice shape in advance, following which crystal growth is performed again to thereby form the semiconductor stacks 12 configuring the light emitting sections (e.g., the light emitting sections A1, A2, A3, A4, A5, and A6) in the openings 16H of the separation section 16. This makes it possible to make spacings between the light emitting sections A1, A2, A3, A4, A5, and A6 smaller. In other words, it is possible to reduce the occupation rate of the separation section 16 in the light emitting device 1. Further, it is possible to form the light emitting sections (the semiconductor stacks 12) without damage resulting from the manufacturing process. In the light emitting device 1 formed by the above-described method, the top surface (the surface 16S1) of the separation section 16 is formed at a position higher than the active layers 14 included in the semiconductor stacks 12.

As described above, the light emitting device 1 of the present embodiment makes it possible to reduce the occupation rate of the separation section 16 in the light emitting device 1 because the separation section 16 for separating the light emitting sections (e.g., the light emitting sections A1, A2, A3, A4, A5, and A6) from each other is formed in advance and thereafter crystal growth is performed again to thereby form the semiconductor stacks 12 configuring the light emitting sections between portions of the separation section 16, specifically, in the openings 16H of the separation section 16 having a lattice shape. Further, it is possible to form the light emitting sections without damage resulting from the manufacturing process. Accordingly, it is possible to improve the light emission efficiency of the light emitting device 1 and to achieve reduction in size thereof. Further, in the image display apparatus 100 including the same, it is possible to achieve higher definition.

Next, a second embodiment and Modification Examples 1 to 4 of the present disclosure will be described. Note that components corresponding to those of the light emitting device 1 of the first embodiment described above are denoted by the same reference numerals, and descriptions thereof will be omitted.

### 2. Second Embodiment

FIG. 13 schematically illustrates an example of a cross-sectional configuration of a light emitting device (a light emitting device 2) according to the second embodiment of the present disclosure. Note that FIG. 13 illustrates a cross section taken along line I-I illustrated in FIG. 2, as with the light emitting device 1 of the first embodiment described above. The light emitting device 2 is suitably applicable as a display pixel of an image display apparatus (the image display apparatus 100) that is what is called an LED display, and includes multiple light emitting sections (light emitting regions).

### 2-1. Configuration of Light Emitting Device

The light emitting device 2 includes the substrate 10, the semiconductor layer 11, the semiconductor stacks 12 that configure the multiple light emitting sections (e.g., the light emitting sections A1, A2, A3, A4, A5, and A6), and a separation section 26 provided between the multiple light emitting sections. In the light emitting device 2, the substrate 10 and the semiconductor layer 11 are stacked in this order, and the multiple semiconductor stacks 12 and the separation section 26 separating the multiple light emitting sections from each other are provided on the semiconductor layer 11. The light emitting device 2 of the present embodiment is different from the first embodiment described above in that the separation section 26 includes a semiconductor material that configures the semiconductor stacks 12.

The separation section 26 electrically separates the multiple light emitting sections (e.g., the light emitting sections A1, A2, A3, A4, A5, and A6) from each other, and is provided in a lattice shape on the semiconductor layer 11, for example. As described above, the separation section 26 of the present embodiment includes a semiconductor material that configures the semiconductor stacks 12. Specifically, the separation section 26 includes a so-called undoped layer that includes a semiconductor material containing no impurities. It is possible to form the separation section 26 by the following method, for example.

### 2-2. Method of Manufacturing Light Emitting Device

First, in a manner similar to that in the first embodiment described above, the semiconductor layer 11 including, for example, GaN, is formed as the underlying layer on the surface 10S1 of the substrate 10 into a thickness of 500 nm to 3000 nm, for example. Subsequently, in a manner similar to that in the first embodiment described above, the dielectric film 16A including, for example, silicon oxide (SiO), is formed on the entire surface of the semiconductor layer 11 into a thickness of, for example, 100 nm to 2000 nm. Next, as illustrated in FIG. 14A, the openings 16H in which the semiconductor layer 11 is exposed are formed in the dielectric film 16A, and thereafter, in a manner similar to that in the first embodiment described above, crystal growth is performed again as selective growth to thereby form the semiconductor stacks 12 configuring the multiple light emitting sections (e.g., the light emitting sections A1 and A2).

Subsequently, as illustrated in FIG. 14B, the dielectric film 16A is removed by, for example, etching, following which a semiconductor layer (a GaN layer) containing no impurities is grown from the side surface of each of the light emitting sections A1 and A2 in a direction parallel to (a direction horizontal to) the substrate surface. The GaN layer extending in the horizontal direction comes into contact with another GaN layer extending similarly in the horizontal direction from the adjacent light emitting section. The GaN layer is thereby formed over the entire surface of the substrate 10. The separation section 26 is thus formed between the multiple light emitting sections (e.g., the light emitting sections A1, A2, A3, A4, A5, and A6). The light emitting device 2 illustrated in FIG. 13 is completed thus.

Note that in the light emitting device 2 fabricated by the above-described method, as illustrated in FIG. 5, for example, the top surface (the surface 15S1) of the second conductivity type layer 15 included in the semiconductor stack 12 and the top surface (the surface 16S1) of the separation section 16 are in one plane.

### 2-3. Workings and Effects

As described above, in the present embodiment, the separation section 26 includes an undoped layer that includes the semiconductor material configuring the semiconductor stacks 12. With the light emitting device 2 having such a configuration also, it is possible to obtain similar effects to those of the first embodiment described above. Furthermore, the present embodiment makes it possible to simplify the manufacturing process as compared with the first embodiment described above.

### 3. Modification Examples

### 3-1. Modification Example 1

FIG. 15 schematically illustrates an example of a cross-sectional configuration of a light emitting device (a light emitting device 3) according to Modification Example 1 of the present disclosure. The light emitting device 3 of the present modification example is a combination of the first embodiment and the second embodiment described above, and includes a separation section 36 having a stacked structure including a dielectric film 36A and an undoped layer 36B having an insulating property.

It is possible to manufacture the light emitting device 3 of the present modification example in the following manner. For example, in a manner similar to that in the first embodiment described above, the semiconductor layer 11 including, for example, GaN, is formed as the underlying layer on the surface 10S1 of the substrate 10 into a thickness of 500 nm to 3000 nm, for example. Subsequently, a dielectric film including, for example, silicon oxide (SiO), is formed on the entire surface of the semiconductor layer 11 into a thickness of, for example, 100 nm to 2000 nm, following which, in a manner similar to that in the first embodiment described above, openings 36H in which the semiconductor layer 11 is exposed are formed in the dielectric film. Thereafter, crystal growth is performed again as selective growth. At this time, the GaN layer configuring the first conductivity type layer 13 grows in the opening 36H in the direction of the normal to the substrate surface, and thereafter grows in the direction parallel to (the direction horizontal to) the substrate surface. Thus, the GaN layer is formed also on the dielectric film 36A. The GaN layer extending in the horizontal direction on the dielectric film 36A comes into contact with another GaN layer extending similarly in the horizontal direction from the adjacent opening 36H. The GaN layer is thereby formed over the entire surface of the substrate 10, for example. The light emitting device 3 illustrated in FIG. 15 is completed thus.

As described above, in the present modification example, the separation section 36 is formed that includes the dielectric film 36A and the undoped layer 36B including the semiconductor material configuring the semiconductor stacks 12. With the light emitting device 3 having such a configuration also, it is possible to obtain similar effects to those of the first embodiment described above. Furthermore, it is possible to simplify the manufacturing process as compared with the second embodiment described above.

### 3-2. Modification Example 2

FIG. 16 schematically illustrates an example of a cross-sectional configuration of a light emitting device (a light emitting device 4) according to Modification Example 2 of the present disclosure. In the light emitting device 4 of the present modification example, for example, grooves 36T are provided in the separation section 36 having a configuration similar to that in Modification Example 1 described above, an electrically conductive film 37 configuring a contact electrode of each of the light emitting sections, for example, is provided on a top surface of the light emitting device 4, and the grooves 36T are filled with the electrically conductive film 37. The electrically conductive film 37 may include a metal material having a light reflecting property, for example.

It is possible to manufacture the light emitting device 4 of the present modification example in the following manner. For example, in a manner similar to that in Modification Example 2 described above, the openings 36H in which the semiconductor layer 11 is exposed are formed and thereafter, crystal growth is performed again as selective growth. At this time, the growth of the GaN layer configuring the first conductivity type layer 13 in the horizontal direction on the dielectric film 36A is stopped before the GaN layer comes into contact with another GaN layer extending similarly in the horizontal direction from the adjacent opening 36H. Thereafter, on the GaN layer, an InGaN layer, for example, configuring the active layer 14 and a GaN layer, for example, configuring the second conductivity type layer 15 are grown in order. The grooves 36T extending toward the surface 10S1 of the substrate 10 are thereby formed. Next, the electrically conductive film 37 is formed on the semiconductor stacks 12 and the separation section 36, and in the grooves 36T. The light emitting device 4 illustrated in FIG. 16 is completed thus.

As described above, in the present modification example, the grooves 36T are formed in the separation section 36 by stopping the growth of the GaN layer extending in the horizontal direction on the dielectric film 36A before the GaN layer comes into contact with another GaN layer extending similarly in the horizontal direction from the adjacent opening 36H, and the grooves 36T are filled with the electrically conductive film 37 configuring a contact electrode common to the light emitting sections (e.g., the light emitting sections A1 and A2). This makes it possible to confine light emission of the active layer 14 for each light emitting section. Accordingly, it is possible to achieve an improved light blocking effect in addition to the effects of the first embodiment described above.

### 3-3. Modification Example 3

FIG. 17 schematically illustrates an example of a cross-sectional configuration of a light emitting device (a light emitting device 5) according to Modification Example 3 of the present disclosure. In the light emitting device 5 of the present modification example, for example, the bottom surface (the back surface (the surface S2) side of the light emitting device 3) of the first conductivity type layer 13 of the semiconductor stack 12 as illustrated in FIG. 9D serves as the light extraction surface. In the case where the back surface (the surface S2) side of the light emitting device 3 is to serve as the light extraction surface as described above, for example, openings 10H penetrating the substrate 10 may be provided at positions opposed to the respective light emitting sections (e.g., the light emitting sections A1 and A2) without removing the substrate 10.

Further, for example, light blocking films 38 may be formed on side surfaces 10S3 of the openings 10H. This makes it possible to reduce the occurrence of color mixture between adjacent pixels. Furthermore, the respective color conversion layers 31R, 31G, and 31B may be provided in the openings 10H.

### 3-4. Modification Example 4

FIG. 18 is a perspective diagram illustrating another configuration example of the image display apparatus (an image display apparatus 200) that uses the light emitting device of the present disclosure (e.g., the light emitting device 1). The image display apparatus 200 is what is called a tiling display that uses LEDs as light sources, in which the light emitting device 1 of the present embodiment is used as a display pixel. The image display apparatus 200 includes, for example, as illustrated in FIG. 18, a display panel 210 and a control circuit 240 that drives the display panel 210.

The display panel 210 includes a mounting substrate 220 and a counter substrate 230 that are superimposed on each other. A surface of the counter substrate 230 serves as an image displaying surface, and has a display region in the middle part and a frame region as a non-display region around the middle part (neither illustrated). The counter substrate 230 is disposed at a position opposed to the mounting substrate 220 with a predetermined spacing therebetween, for example. Note that the counter substrate 230 may be in contact with a top surface of the mounting substrate 220.

FIG. 19 schematically illustrates an example of a configuration of the mounting substrate 220. For example, the mounting substrate 220 may include multiple unit substrates 250 that are tiled, as illustrated in FIG. 19. Note that although FIG. 19 illustrates an example in which the mounting substate 220 includes nine unit substrates 250, the number of the unit substrates 250 may be ten or more, or may be eight or less.

FIG. 20 illustrates an example of a configuration of the unit substrate 250. The unit substrate 250 includes, for example, the light emitting devices 1 that are tiled and include multiple light emitting sections (e.g., the light emitting sections A1, A2, A3, A4, A5, and A6), and a support substrate 260 supporting each of the light emitting devices 1. Each unit substrate 250 further includes a control substrate (not illustrated). The support substrate 260 is configured by, for example, a metal frame (a metal plate), a wiring substrate (e.g., the wiring substrate 22 described above), or the like. In a case where the support substrate 260 is configured by the wiring substrate, the support substrate 260 may also serve as the control substrate. At this time, the support substrate 260, the control substrate, or both are electrically coupled to each light emitting device 1.

Although the present disclosure has been described above with reference to the first and second embodiments and Modification Examples 1 to 4, the present disclosure is not limited to the above embodiments and the like, and various modifications can be made.

For example, in the above embodiments and the like, the light emitting device (e.g., the light emitting device 1) having a flat-surface shape is illustrated; however, using the present technology makes it possible to easily form a light emitting device having a curved-surface shape.

Note that the effects described herein are merely illustrative and not limitative, and other effects may be achieved.

The present technology may also be configured as follows. According to the present technology having the following configurations, on the first surface side of the substrate, the separation section having the top surface at a position higher than the active layer in the direction of the normal to the first surface of the substrate is provided between the multiple light emitting regions of the semiconductor stacks each including the first conductivity type layer, the active layer, and the second conductivity type layer that are stacked. The separation section is formed in advance on the first surface of the substrate, and the semiconductor stacks including the respective light emitting regions are separated by the separation section at the time of crystal growth. This prevents damage to the semiconductor stacks resulting from the manufacturing process and makes the spacings between the light emitting regions smaller. Accordingly, it is possible to improve the light emission efficiency and to achieve a reduction in size.
(1) A light emitting device including:
   a substrate having a first surface and a second surface opposed to each other;
   semiconductor stacks provided on the first surface of the substrate and each including a first conductivity type layer, an active layer, and a second conductivity type layer that are stacked in order from a side of the first surface, the semiconductor stacks including multiple light emitting regions configured to emit light; and
   a separation section provided between the multiple light emitting regions and having a top surface at a position higher than the active layer in a direction of a normal to the first surface of the substrate.
(2) The light emitting device according to (1), in which the multiple light emitting regions are to be driven independently of each other.
(3) The light emitting device according to (1) or (2), in which the semiconductor stacks have top surfaces at a position higher than that of the top surface of the separation section, and the second conductivity type layer extends onto a portion of the top surface of the separation section.
(4) The light emitting device according to (1) or (2), in which top surfaces of the semiconductor stacks form one plane with the top surface of the separation section.
(5) The light emitting device according to (1) or (2), in which the semiconductor stacks have top surfaces at a position lower than that of the top surface of the separation section.
(6) The light emitting device according to (5), in which the separation section has a side surface on a side surface of each of the semiconductor stacks in contact with the separation section and on an extended line thereof.
(7) The light emitting device according to any one of (1) to (6), in which the separation section includes an insulator including a dielectric material.
(8) The light emitting device according to (7), in which the dielectric material includes an oxide material or a nitride material.
(9) The light emitting device according to any one of (1) to (6), in which the separation section includes a semiconductor material that configures the semiconductor stacks.
(11) The light emitting device according to any one of (1) to (10), in which the separation section has a stacked structure including a first separation layer including a dielectric material and a second separation layer including a semiconductor material that configures the semiconductor stacks.
(12) The light emitting device according to any one of (1) to (11), further including a first electrically conductive film on the top surfaces of the semiconductor stacks.
(13) The light emitting device according to (12), in which
   the separation section has a groove extending from the top surface in a direction toward the first surface of the substrate, and
   the groove is filled with the first electrically conductive film.
(14) The light emitting device according to (13), in which the first electrically conductive film has a light reflecting property.
(15) The light emitting device according to any one of (1) to (14), in which the multiple light emitting regions emit the light from a side of the substrate.
(16) The light emitting device according to any one of (1) to (15), in which the substrate has multiple openings at respective positions directly opposed to the multiple light emitting regions.
(17) A method of manufacturing a light emitting device, including
   after forming a separation section on a first surface of a substrate having the first surface and a second surface opposed to each other,
   forming semiconductor stacks with the separation section interposed therebetween, the semiconductor stacks each including a first conductivity type layer, an active layer, and a second conductivity type layer that are stacked in order from a side of the first surface, the semiconductor stacks including multiple light emitting regions configured to emit light.
(18) The method of manufacturing the light emitting device according to (17), including
   after forming the separation section entirely on the first surface,
   forming multiple openings that penetrate the separation section, and growing the first conductivity type layer, the active layer, and the second conductivity type layer in order on the first surface exposed in each of the openings.
(19) The method of manufacturing the light emitting device according to (17), including
   after growing the first conductivity type layer, the active layer, and the second conductivity type layer in order,
   forming the separation section by growing a semiconductor layer in a direction parallel to the first surface of the substrate, the semiconductor layer containing no impurities and configuring the first conductivity type layer and the second conductivity type layer.
(20) An image display apparatus including multiple light emitting devices, the light emitting devices each including:
   a substrate having a first surface and a second surface opposed to each other;
   semiconductor stacks provided on the first surface of the substrate and each including a first conductivity type layer, an active layer, and a second conductivity type layer that are stacked in order from a side of the first surface, the semiconductor stacks including multiple light emitting regions configured to emit light; and
   a separation section provided between the multiple light emitting regions and having a top surface at a position higher than the active layer in a direction of a normal to the first surface of the substrate.

The present application claims the priority on the basis of Japanese Patent Application No. 2020-027216 filed with the Japan Patent Office on Feb. 20, 2020, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light emitting device, comprising:
a substrate having a first surface and a second surface opposed to each other;
semiconductor stacks provided on the first surface of the substrate and each including a first conductivity type layer, an active layer, and a second conductivity type layer that are stacked in order from a side of the first surface, the semiconductor stacks including multiple light emitting regions configured to emit light; and
a separation section provided between the multiple light emitting regions and having a top surface at a position higher than the active layer in a direction of a normal to the first surface of the substrate.

2. The light emitting device according to claim 1, wherein the multiple light emitting regions are to be driven independently of each other.

3. The light emitting device according to claim 1, wherein the semiconductor stacks have top surfaces at a position higher than that of the top surface of the separation section, and the second conductivity type layer extends onto a portion of the top surface of the separation section.

4. The light emitting device according to claim 1, wherein top surfaces of the semiconductor stacks form one plane with the top surface of the separation section.

5. The light emitting device according to claim 1, wherein the semiconductor stacks have top surfaces at a position lower than that of the top surface of the separation section.

6. The light emitting device according to claim 5, wherein the separation section has a side surface on a side surface of each of the semiconductor stacks in contact with the separation section and on an extended line thereof.

7. The light emitting device according to claim 1, wherein the separation section includes an insulator including a dielectric material.

8. The light emitting device according to claim 7, wherein the dielectric material comprises an oxide material or a nitride material.

9. The light emitting device according to claim 1, wherein the separation section includes a semiconductor material that configures the semiconductor stacks.

10. The light emitting device according to claim 9, wherein the separation section includes an undoped layer including the semiconductor material that configures the semiconductor stacks.

11. The light emitting device according to claim 1, wherein the separation section has a stacked structure including a first separation layer including a dielectric material and a second separation layer including a semiconductor material that configures the semiconductor stacks.

12. The light emitting device according to claim 1, further comprising a first electrically conductive film on the top surfaces of the semiconductor stacks.

13. The light emitting device according to claim 12, wherein
the separation section has a groove extending from the top surface in a direction toward the first surface of the substrate, and
the groove is filled with the first electrically conductive film.

14. The light emitting device according to claim 13, wherein the first electrically conductive film has a light reflecting property.

15. The light emitting device according to claim 1, wherein the multiple light emitting regions emit the light from a side of the substrate.

16. The light emitting device according to claim 1, wherein the substrate has multiple openings at respective positions directly opposed to the multiple light emitting regions.

17. A method of manufacturing a light emitting device, comprising
after forming a separation section on a first surface of a substrate having the first surface and a second surface opposed to each other,
forming semiconductor stacks with the separation section interposed therebetween, the semiconductor stacks each including a first conductivity type layer, an active layer, and a second conductivity type layer that are stacked in order from a side of the first surface, the semiconductor stacks including multiple light emitting regions configured to emit light.

18. The method of manufacturing the light emitting device according to claim 17, comprising
after forming the separation section entirely on the first surface,
forming multiple openings that penetrate the separation section, and growing the first conductivity type layer, the active layer, and the second conductivity type layer in order on the first surface exposed in each of the openings.

19. The method of manufacturing the light emitting device according to claim 17, comprising
after growing the first conductivity type layer, the active layer, and the second conductivity type layer in order,
forming the separation section by growing a semiconductor layer in a direction parallel to the first surface of the substrate, the semiconductor layer containing no impurities and configuring the first conductivity type layer and the second conductivity type layer.

20. An image display apparatus comprising multiple light emitting devices,
the light emitting devices each including:
a substrate having a first surface and a second surface opposed to each other;
semiconductor stacks provided on the first surface of the substrate and each including a first conductivity type layer, an active layer, and a second conductivity type layer that are stacked in order from a side of the first surface, the semiconductor stacks including multiple light emitting regions configured to emit light; and
a separation section provided between the multiple light emitting regions and having a top surface at a position higher than the active layer in a direction of a normal to the first surface of the substrate.
